(19) United States
(12) Patent Application Publication
(10) Pub. No.: US 2014/0311560 A1
(43) Pub. Date: Oct. 23, 2014

(54) MULTILAYER LAMINATE FOR PHOTOVOLTAIC APPLICATIONS

(71) Applicant: Saint-Gobain Performance Plastics Corporation, Aurora, OH (US)

(72) Inventors: Chinmay S. Betrabet, San Diego, CA (US); Raymond B. Turner, San Diego, CA (US)

(73) Assignee: Saint-Gobain Performance Plastics Corporation, Aurora, OH (US)

(21) Appl. No.: 14/253,148

(22) Filed: Apr. 15, 2014

Related U.S. Application Data
(60) Provisional application No. 61/813,080, filed on Apr. 17, 2013.
(60) Provisional application No. 61/840,497, filed on Jun. 28, 2013.

(51) Int. Cl. H01L 31/048; H01L 31/18

(52) U.S. Cl. CPC H01L 31/0487; H01L 31/18
USPC 136/256; 438/98

(57) ABSTRACT

A multilayer laminate for a photovoltaic device includes a barrier polymer layer. The barrier polymer layer includes a fluoropolymer layer disposed on a polyester layer. A polymeric support layer is disposed on the polyester layer of the barrier polymer layer and a conductive layer is disposed on the polymeric support layer. The conductive layer includes a copper layer disposed on an aluminum layer, wherein the conductive layer is patterned.

### CROSS-REFERENCE TO RELATED APPLICATION

The present application claims priority to and the benefit of U.S. Provisional Patent Application No. 61/813,080, filed Apr. 17, 2013, entitled “MULTILAYER LAMINATE FOR PHOTOVOLTAIC APPLICATIONS,” naming as inventors Chinmay S. Betrabet and Raymond B. Turner, and claims priority to and the benefit of U.S. Provisional Patent Application No. 61/840,497, filed Jun. 28, 2013, entitled “MULTILAYER LAMINATE FOR PHOTOVOLTAIC APPLICATIONS,” naming as inventors Chinmay S. Betrabet and Raymond B. Turner, which applications are incorporated by reference herein in their entirety.

### FIELD OF THE DISCLOSURE

This disclosure, in general, relates to multilayer laminates and photovoltaic devices formed therewith.

### BACKGROUND

As economies around the world grow, demand for energy is increasing. As a result, the price of traditional fossil fuel energy sources is increasing. However, increased usage of fossil fuel sources has disadvantages such as detrimental environmental impact and theorized limits in supply.

Governments and energy industries are looking toward alternative energy sources for fulfilling future supply requirements. However, alternate energy sources have a higher per kilowatt-hour cost than traditional fossil fuel sources. One such alternate energy source is solar power. In typical solar power systems, photovoltaic devices absorb sunlight to produce electrical energy. Typical photovoltaic devices include photovoltaic cells sandwiched between a backsheet of polymer laminates and the like and glass that is sealed and held together in a framed structure. As the power output of the photovoltaic cell is increased, the backsheet of the photovoltaic device becomes an important part of the structure. In particular, the backsheet may be used to not only withstand environmental forces for long periods of time, i.e. up to several decades, but also be structured to increase the efficiency of the photovoltaic device.

As such, an improved photovoltaic device would be desirable.

### SUMMARY

In an embodiment, a multilayer laminate for a photovoltaic device includes a barrier polymer layer including a fluoropolymer layer disposed on a polyester layer; a polymeric support layer disposed on the polyester layer of the barrier polymer layer; and a patterned conductive layer including a copper layer disposed on an aluminum layer, the aluminum layer disposed on the polymeric support layer.

In another embodiment, a method of making a multilayer laminate for a photovoltaic device is provided. The method includes providing a barrier polymer layer including a fluoropolymer layer disposed on a polyester layer; disposing a conductive layer on a polymeric support layer, the conductive layer including a copper layer disposed on an aluminum layer, wherein the conductive layer is patterned; and disposing the polymeric support layer on the polyester layer of the barrier polymer layer.

In yet another embodiment, a photovoltaic device is provided. The photovoltaic device includes a multilayer laminate backsheet including a barrier polymer layer including a fluoropolymer layer disposed on a polyester layer; a polymeric support layer disposed on the polyester layer of the barrier polymer layer; and a patterned conductive layer including a copper layer disposed on an aluminum layer, the aluminum layer disposed on the polymeric support layer.

### BRIEF DESCRIPTION OF THE DRAWINGS

The present disclosure may be better understood, and its numerous features and advantages made apparent to those skilled in the art by referencing the accompanying drawings.

FIG. 1 includes an exemplary illustration of a multilayer laminate.

FIG. 1A includes an exemplary illustration of a portion of a multilayer laminate.

FIG. 1B includes an exemplary illustration of a multilayer laminate.

FIG. 2 includes an exemplary illustration of a photovoltaic device.

The use of the same reference symbols in different drawings indicates similar or identical items.

### DESCRIPTION OF THE PREFERRED EMBODIMENT(S)

The following description in combination with the figures is provided to assist in understanding the teachings disclosed herein. The following discussion will focus on specific implementations and embodiments of the teachings. This focus is provided to assist in describing the teachings and should not be interpreted as a limitation on the scope or applicability of the teachings. However, other teachings can certainly be used in this application.

In an embodiment, a multilayer laminate for a photovoltaic device is provided. The multilayer laminate includes a barrier polymer layer; a polymeric support layer disposed on the barrier polymer layer; and a conductive layer including a copper layer disposed on an aluminum layer, the aluminum layer disposed on the polymeric support layer. In a particular embodiment, the conductive layer is patterned. The multilayer laminate is typically provided within a photovoltaic device, for instance, as a backsheet for the photovoltaic device. The multilayer laminate provides an improved structure and the process for making the multilayer laminate increases the efficiency and lowers the cost of the resulting photovoltaic device.

In the embodiments described herein, the photovoltaic device includes at least two major surfaces. The term “front surface” refers to the surface of the photovoltaic device that receives the greater proportion of direct sunlight. In embodiments, the front surface is the active side of the photovoltaic device that converts sunlight to electricity. However, in some embodiments, the photovoltaic device can be constructed such that two surfaces of the device are active. For example, the front surface can convert direct sunlight to electricity, while the back surface can convert reflected sunlight to electricity. The embodiments described herein can include such photovoltaic constructions or other similar photovoltaic constructions. The terms “over,” “overlie,” “under,” or “underlie” refer to the disposition of a layer, film or laminate relative to a major surface of an adjacent structure in which “over” or “overlie” mean the layer, film or laminate is relatively closer to an outer surface of a photovoltaic device and “under” or “underlie” mean the layer, film or laminate is relatively further from an outer surface of the photovoltaic device. Herein, the terms “on,” “over,” “overlie,” “under,” and “underlie” can permit inclusion of intermediate structures between the surface and the recited structure.

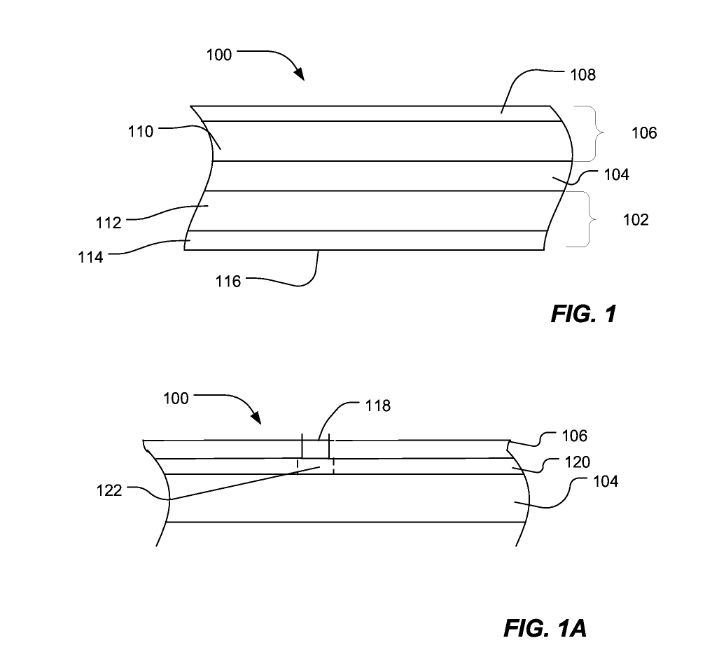

As illustrated in FIG. 1, a multilayer laminate 100 includes a barrier polymer layer 102. Further included in the multilayer laminate 100 is a polymeric support layer 104 disposed on the barrier polymer layer 102. A conductive layer 106 is provided with an inorganic layer to draw an electrical current away from a photovoltaic cell and in an embodiment, to transport the current to usable energy. For example, the inorganic layer can include metal, metal oxide, metal nitride, metal carbide, or a combination thereof. In an example, the metal can include aluminum, copper, silver, gold, titanium, tin, zinc, bismuth, nickel, vanadium, or a combination thereof. An exemplary metal oxide can include alumina, silica, tin oxide, zinc oxide, or a combination thereof. An exemplary metal nitride can include aluminum nitride, titanium nitride, silicon nitride, zinc nitride or a combination thereof. An exemplary carbide can include silicon carbide, aluminum carbide, titanium carbide, or a combination thereof.

In an embodiment, the thickness and material choice for the conductive layer is chosen due to the conductivity and cost of the material. For instance, copper is an ideal material due to its conductivity. The high cost of copper, however, is detrimental to mass production of photovoltaic modules. Aluminum is cheaper than copper but less conductive. In addition, the oxidation of aluminum further decreases its conductivity. Conventional conductive backsheets typically include a single inorganic layer. In an embodiment of the present invention, a combination of materials may be used for the conductive layer 106. In a particular embodiment, a combination of aluminum and copper may be used. The combination of aluminum and copper is cheaper than a single layer of copper, for the same conductivity. Further, a copper layer 108 disposed on an aluminum layer 110 prevents the oxidation of the aluminum layer 110. In an embodiment, any disposition of the layers is envisioned. In an embodiment, the conductive layer 106 includes the copper layer 108 directly disposed on the aluminum layer 110, the aluminum layer 110 disposed on the polymeric support layer 104. In an exemplary embodiment, the aluminum layer 110 is an aluminum foil. In a particular embodiment, each of the aluminum layer 110 and the copper layer 108 has a thickness to provide an efficiently conductive surface as well as a cost efficient product, where the product cost can be reduced by more than 10%. For instance, the aluminum layer 110 has a thickness of about 4 micrometers to about 100 micrometers, such as about 25 micrometers to about 100 micrometers. In an embodiment, the copper layer 108 has a thickness of about 10 nanometers to about 300 nanometers.

In a particular embodiment, the conductive layer 106 may be patterned. Any portion of the conductive layer 106 may be patterned. For instance, the conductive layer 106 is patterned such that the copper layer 108, the aluminum layer 110, or combination thereof forms a pattern on the backsheet 100. Any pattern is envisioned. In a particular embodiment, the conductive layer 106 is patterned to provide electrical isolation within the conductive layer 106, i.e. through dielectric separation. Further, the use of a pattern may provide a reduced amount of material for at least a portion of the conductive layer 106, such as the copper layer 108, the aluminum layer 110, or combination thereof, compared to a continuous layer without any pattern. Additionally, the conductive pattern 106 may also provide other advantages such as desirable aesthetics and modulation of a reflection of solar energy. In an embodiment, the pattern may be the same or different for any portion of the conductive layer. For instance, the copper layer 108 may have a pattern that is the same or different than a pattern on the aluminum layer 110. Patterning may include at least one shaped portion, such as at least one discrete point, at least one strip, at least one polygon, or any combination thereof. The patterned conductive layer 106 may be used with any reasonable electronic device, such as a capacitor, a two-terminal device, a metal wrap through solar cell, an emitter wrap through solar cell, or an integrated back contact solar cell.

Although not illustrated, any further layers may be envisioned for inclusion in the conductive layer 106. Any disposition of any further layers is envisioned. For instance, an additional metal layer may be disposed on a surface of the aluminum layer 110. In an embodiment, the aluminum layer 110 is sandwiched between the copper layer 108 and the additional metal layer, such an additional copper layer. In another embodiment, an additional layer may include an anti-oxidation layer, or oxidation resistant material. An “anti-oxidation layer” decreases the oxidation rate of the layer it is disposed thereon. For instance, the copper layer 108 may be sandwiched between the aluminum layer 110 and the anti-oxidation layer. In an embodiment, the additional layer may by any oxidation resistant material envisioned such as an inorganic layer, an organic layer, or a combination thereof. For instance, the anti-oxidation layer may include an inorganic layer, for example, tin, silver, nickel, vanadium, bismuth, or combination thereof. In an embodiment, the anti-oxidation layer may be an organic layer, for example, a triazole, such as a benzotriazole. In an embodiment, the anti-oxidation layer is disposed on the surface of the layer that is exposed to oxidation conditions. In an embodiment, the anti-oxidation layer is disposed on the conductive layer that is disposed furthest from the surface of the polymeric support layer 104. In a particular embodiment, the anti-oxidation layer may be disposed on the copper layer 108. The anti-oxidation layer may or may not be patterned. Any thickness of the anti-oxidation layer is envisioned. In an embodiment, the anti-oxidation layer has a thickness of about 1 nanometer to about 50 nanometers, such as about 1 nanometer to about 25 nanometers.

In an embodiment, the conductive layer 106 is disposed on the polymeric support layer 104. In a particular embodiment, the polymeric support layer 104 provides structural integrity to the conductive layer 106. In a particular embodiment, the polymeric support layer 104 provides structure for the conductive layer 106 during processing and forming of the conductive layer 106. In a more particular embodiment, the polymeric support layer 104 has a thickness that is desirable for the efficient processing of the conductive layer 106, such as during the deposition of the copper layer 108 on the aluminum layer 110. For instance, the thickness of the polymeric support layer is about 10 microns to about 325 microns, such as about 10 microns to about 75 microns. In an embodiment, the polymeric support layer 104 is particularly useful for support of the conductive layer 106 during post processing after the conductive layer 106 has been disposed thereon, such as for patterning, die cutting, peeling, vacuuming, or combination thereof.

The polymeric support layer 104 may be any polymer envisioned for photovoltaic applications, i.e. a polymer that can maintain its structure without degradation during multiple electrical cycles and temperature cycles with temperature extremes of −30° C. to +65° C. In a particular embodiment, the polymeric support layer 104 is chosen to provide insulative properties as well as barrier properties. For instance, any reasonable polymer can be used as the polymeric support layer 104 to function as a barrier to hinder water vapor transmission, corrosive gas diffusion, UV light transmission, or any combination thereof.

Particular materials that may be used as the polymeric support layer 104 help protect the photovoltaic device and include, for example, materials used as an encapsulant. The encapsulant may include natural or synthetic polymers including polyethylene (including linear low density polyethylene, low density polyethylene, high density polyethylene, etc.), polypropylene, nylon (polyamide), EPDM, polyester, polycarbonate, ethylene-propylene elastomer copolymer, copolymer of ethylene or propylene with acrylic or methacrylic acid, acrylate, methacrylate, ethylene-propylene copolymer, poly alpha olefin melt adhesive including, for example, ethylene vinyl acetate (EVA), ethylene butyl acrylate (EBA), ethylene methyl acrylate (EMA); ionomer (acid functionalized polyolefin generally neutralized as a metal salt), acid functionalized polyolefin, polyurethane including, for example, thermoplastic polyurethane (TPU), olefin elastomer, olefinic block copolymer, thermoplastic silicone, polyvinyl butyral, a fluoropolymer, such as a terpolymer of tetrafluoroethylene, hexafluoropropylene, and vinylidene fluoride; or any combination thereof.

An exemplary polymer for the polymeric support layer 104 includes polyester, polycarbonate, or any combination thereof. An exemplary polyester can include polyethylene terephthalate (PET), such as those available under the tradenames such as Skyrol, Melinex, or Mylar, or polyethylene naphthalate (PEN). In another example, the polyester includes a liquid crystal polymer. An exemplary liquid crystal polymer includes aromatic polyester polymers, such as those available under tradenames XYDAR® (Amoco), VECTRA® (Hoechst Celanese), SUMIKOSUPER™ or EKONOL™ (Sumitomo Chemical), DuPont HX™ or DuPont ZENITE™ (E.I. DuPont de Nemours), RODRUN™ (Unitika), GRANLAR™ (Grandmont), or any combination thereof. Preferred liquid crystal polymers include thermotropic (melt processable) liquid crystal polymers wherein constrained microlayer crystallinity can be particularly advantageous. Although not illustrated, in an embodiment, the multilayer laminate 100 does not contain a polymeric support layer 104. For instance, the conductive layer 106 may be disposed on the barrier polymer layer 102 without any intervening polymeric support layer 104.

Further included in the multilayer laminate 100 is the barrier polymer layer 102. The barrier polymer layer 102 typically provides a seal and protective properties to a device, such as a photovoltaic cell, from an external environment. For instance, the barrier polymer layer 102 is provided to inhibit water vapor transfer, corrosive gas transfer, such as oxygen transfer, UV light transmission, or a combination thereof. For example, the barrier polymer layer 102 can have a water vapor transmission rate of not greater than 0.8 g/m² day, such as not greater than 0.4 g/m² day, or even not greater than 0.2 g/m² day.

In an embodiment, the barrier polymer layer 102 may be any polymer as described above for the polymeric support layer 104. For instance, the barrier polymer layer 102 may include any of the encapsulant materials as described above. Any number of layers may be envisioned for the barrier polymer layer 102. In a particular embodiment, the barrier polymer layer 102 is a multilayer film. For instance, the barrier polymer layer 102 has a polyester layer 112 and a fluoropolymer layer 114. In a particular embodiment, the polyester layer 112 is a polyethylene terephthalate. In an embodiment, the polyester layer has a thickness of about 12 micrometers to about 325 micrometers, such as about 12 micrometers to about 275 micrometers. When the barrier polymer layer 102 is a multilayer film, any disposition of the layer(s) for the barrier polymer layer 102 is envisioned.

In a particular example, the fluoropolymer layer 114 forms an outer surface 116 of the barrier polymer layer 102. For instance, the fluoropolymer layer 114 provides the outer surface 116 that contacts the external environment. Exemplary fluoropolymers include polyvinylidene fluoride (PVDF), polyvinyl fluoride (PVF), polytetrafluoroethylene (PTFE), a copolymer of tetrafluoroethylene and perfluoro methylvinylether (PFA), ethylene tetrafluoroethylene copolymer (ETFE), polychlorotrifluoroethylene (PCTFE), ethylene chlorotrifluoroethylene copolymer (ECTFE), fluorinated ethylene propylene copolymer (FEP), a copolymer of ethylene and fluorinated ethylene propylene (EFEP), a terpolymer of tetrafluoroethylene, hexafluoropropylene, and vinylidene fluoride (THV), a terpolymer of tetrafluoroethylene, hexafluoropropylene, and ethylene (HTE), or any combination thereof. In an embodiment, the fluoropolymer may include any reasonable functional groups to facilitate the cross-linking of any monomers used to form the fluoropolymer. In a particular example, the fluoropolymer layer 114 includes at least 70% fluoropolymer, such as at least 85% fluoropolymer, at least 95% fluoropolymer, at least 98% fluoropolymer, or consists essentially of fluoropolymer. In a particular example, the fluoropolymer layer 114 includes ethylene-tetrafluoroethylene copolymer (ETFE). In another example, the fluoropolymer layer 114 includes fluorinated ethylene propylene copolymer (FEP). In a further example, the fluoropolymer layer 114 includes polyvinyl fluoride (PVF). The fluoropolymer layer 114 has both desirable chemical resistance and weatherability for exposure to the external environment. In an embodiment, the fluoropolymer layer has a thickness of about 1 micrometer to about 50 micrometers, such as about 1 micrometer to about 30 micrometers. Although not illustrated, the barrier layer 102 may further include a metal layer as the outer surface of the multilayer laminate 100, with or without a fluoropolymer layer 114 disposed therebetween. For instance, a metal layer, such as a layer of aluminum foil is envisioned and in particular, with a thickness of about 6 microns to about 75 microns, such as a thickness of about 6 microns to about 50 microns.

Any reasonable layer may further be envisioned within the multilayer laminate 100. Exemplary layers include an adhesive layer, a reinforcing layer, or any combination thereof. Further layers may include a layer that confers opacity against UV and visible light, color, improved dielectric resistance, or any combination thereof. A reinforcing layer can include a reinforcement, such as a fibrous reinforcement. Any reinforcement material may be envisioned such as a polymer, a glass, a metal, or combination thereof. The fibrous reinforcement can be a woven fibrous reinforcement or a non-woven fibrous reinforcement. In an example, the reinforcement is a woven fibrous reinforcement, such as a glass fabric or scrim. The reinforcing layer may be a separate layer or contained within a layer to provide reinforcing properties to the final multilayer laminate 100.

In an embodiment, an adhesive layer may be envisioned to increase the adhesion between adjacent layers. For instance, an adhesive layer may be disposed between the fluoropolymer layer 114 and the polyester layer 112 of the barrier layer 102. In an embodiment, an adhesive layer may be disposed between the polymeric support layer 104 and the barrier layer 102, such as between the polymeric support layer 104 and the polyester layer 112. In an embodiment, an adhesive layer may be disposed between the polymeric support layer 104 and the conductive layer 106. In particular, an adhesive layer may be disposed between the polymeric support layer 104 and the aluminum layer 110. In a more particular embodiment, the adhesive layer may be disposed between the polymeric support layer 104 and the aluminum layer 110 in a pattern. In another embodiment, the adhesive layer may be disposed between the aluminum layer 110 and the copper layer 108. In a more particular embodiment, the adhesive layer may be disposed between the aluminum layer 110 and the copper layer 108 in a pattern. Any pattern within the multilayer laminate 100 may be the same or different between the layers depending upon the final multilayer laminate 100 desired.

An exemplary adhesive includes a polyurethane, an ethylene vinyl acetate (EVA), a polyester, a cynoacrylate, an epoxy, a phenolic, an olefin, a hot melt adhesive, an ionomer, a silicone, an acrylic, a copolymer thereof, or a combination thereof. Alternatively, the adhesive can be formed of an encapsulant, such as an encapsulant described above. In a particular example, the adhesive includes polyurethane, such as an aliphatic polyurethane. In another example, the adhesive includes ethylene vinyl acetate (EVA). In an example, the adhesive is an optically clear adhesive (OCA). An optically clear adhesive is particular advantageous for light transmittance. An OCA has an internal transmittance of at least 99% and a haze of less than 1%. Internal transmittance is calculated in accordance with the definition of internal transmittance found in ASTM E284. Haze is measured in accordance with ASTM D1003-92.

Any method of forming the multilayer laminate 100 may be envisioned. In an embodiment, the method includes providing a barrier polymer layer 102 including a fluoropolymer layer 114 disposed on a polyester layer 112; disposing a conductive layer 106 on a polymeric support layer 104, the conductive layer 106 including a copper layer 108 disposed on an aluminum layer 110; and disposing the polymeric support layer 104 on the polyester layer 112 of the barrier polymer layer 102. In a particular embodiment, the conductive layer 106 is patterned.

In an embodiment, the fluoropolymer layer 114 is disposed on the polyester layer 112 by any reasonable method. For instance, the method is dependent upon the thickness desired and the fluoropolymer chosen. In an embodiment, the fluoropolymer layer 114 is coated or laminated on the polyester layer 112. In a particular embodiment, the fluoropolymer layer 114 is coated on the polyester layer 112. Any coating method is envisioned such as screen printing, roll coating, rod coating, spray coating, dip coating, gravure coating, the like, or any combination thereof. After coating, the fluoropolymer layer 114 may be cured at any temperature, depending upon the fluoropolymer chosen.

In an embodiment, the barrier polymer layer 102 may be heat stabilized. “Heat stabilization” as used herein refers to a method of heating the barrier polymer layer 102 to heat the polyester layer 112 at the maximum use temperature to both relax and shrink the polyester layer 112. In an embodiment, the heat stabilization includes heating the barrier polymer layer at a temperature to not less than about 40° below a glass transition temperature of the polymeric layer within the barrier layer. The heat during heat stabilization may also include curing a coating of the fluoropolymer disposed on the polyester layer 112. In an embodiment, the barrier polymer layer 102 is heated at a temperature such that the polyester layer 112 does not degrade mechanically (i.e. does not lose dimensional stability). In a particular embodiment, the barrier polymer layer 102 is heated to a temperature of at least about 100° C., such as about 100° C. to about 190° C. In an embodiment, “heat stabilization” further includes maintaining a low tension on the barrier polymer layer 102 during heating and cooling of the barrier polymer layer 102. “Low tension” as used herein refers to a tension of less than about 10.0 pounds (lbs.) per lineal foot, such as less than about 7.5 lbs per lineal foot, such as less than about 5.0 lbs per lineal foot, such as less than about 2.5 lbs per lineal foot, or even less than about 1.0 lbs per lineal foot. Any method of heating is envisioned and typically may occur in an oven, such as an air floatation oven, a heated nip, a roller, or combination thereof. In an embodiment, the barrier polymer layer 102 is cooled to ambient temperature (about 30° C.). The barrier polymer layer 102 that has been heat stabilized has a net shrinkage in a machine direction and a cross direction of less than about 2.0%, such as less than about 1.0%, such as less than about 0.5%, or even less than about 0.2%. “Machine direction” as used herein refers to a direction parallel to a long axis, i.e. length, of the barrier polymer layer 102 and “cross direction” as used herein refers to the direction that is parallel to a width of the barrier polymer layer 102. In a particular embodiment, with a heat stabilized barrier polymer layer 102, the net shrinkage, i.e. the physical dimensions of height and length, will not change during any remaining processing of the multilayer laminate 100 and during the production of the photovoltaic device. Net shrinkage is determined through measurements of the dimensions of samples before and after exposing a sampling of the heat stabilized barrier polymer layer 102 to a temperature of 150° Celcius for a time of 30 minutes and determining the overall shrinkage before and after exposure of the sampling. Accordingly, the dimensional stability of the barrier polymer layer 102 is improved compared to a barrier polymer layer 102 that has not been heat stabilized. Advantageously, by combining curing of the fluoropolymer layer 114 with the heating of the polyester layer 112 into a single process, the efficiency of the processing of the multilayer laminate 100 and the photovoltaic device is increased. Ultimately, by decreasing the number of processing conditions, the processing costs of the multilayer laminate 100 and a photovoltaic device is also decreased.

In an embodiment of the production of the multilayer laminate 100, the conductive layer 106 may be disposed on the polymeric support layer 104. In an embodiment, the conductive layer 106 is any inorganic layer as described. In a particular embodiment, the conductive layer 106 includes at least the aluminum layer 110. In an exemplary embodiment, the aluminum layer 110 may be disposed in a pattern. In another embodiment, the aluminum layer 110 is disposed as a continuous, single layer. Any method of disposing the conductive layer 106 on the polymeric support layer 104 is envisioned. For instance, the aluminum layer 110 is disposed on the polymeric support layer 104 with an adhesive (not illustrated). In an embodiment, the adhesive may be a continuous layer or a discontinuous layer on the polymeric support layer 104. In a particular embodiment, the adhesive may be disposed on the polymeric support layer 104 in a pattern. Any method of disposing the adhesive is envisioned and depends on the material chosen. For instance, the adhesive may be laminated or coated.

The aluminum layer 110 may be treated to prevent oxidation of the aluminum. Treatment of the aluminum layer 110 may be before disposal on the polymeric support layer 104, after disposal on the polymeric support layer 104, or any combination thereof. Any additional layer, such as a conductive layer, an anti-oxidation layer, treatment, or combination thereof is envisioned. For instance, the presence of the copper layer 108 prevents the oxidation of the aluminum layer 110. In an embodiment, the copper layer 108 is disposed on the aluminum layer 110 by any reasonable method. In an embodiment, the copper layer is provided in a pattern. Any method of providing the pattern is envisioned, including disposing at least a portion of the conductive layer 106 in a pattern, removing at least a portion of the conductive layer 106, or any combination thereof. “At least a portion of the conductive layer” as used herein refers to at least one anti-oxidation layer such as the copper layer 108, the aluminum layer 110, or any combination thereof. In an embodiment, the surface of the aluminum layer 110 may be pre-treated for removal of any contaminants, aluminum oxide, and the like, prior to deposition of any additional layer. Any pre-treatment is envisioned. Pre-treatment may include, for example, plasma treatment in an atmosphere such as argon, hydrogen, chlorine, or any combination thereof.

For instance, the application of the copper layer and/or the anti-oxidation treatment may be through one or more of a variety of thin film inorganic layer deposition, such as chemical vapor deposition (CVD), plasma enhanced chemical vapor deposition (PECVD), or physical vapor deposition, such as sputtering or evaporative deposition, or a combination thereof. In an embodiment, the copper layer 108 is provided by coating a layer of copper on the aluminum layer 110 through a vapor deposition process such as sputtering, evaporation, electrolytic plating, plasma spray deposition, or combination thereof. In another embodiment, the copper layer 108 is disposed on the aluminum layer 110 by an ultrasonic bonding process. In particular, the ultrasonic bonding process may be used to place the copper layer 108 as a strip, a discrete point, a polygon, or any combination thereof. For instance, a copper-containing foil (CCF) of any reasonable size may be ultrasonically bonded to the aluminum layer 110. In an exemplary embodiment, a pattern of the copper layer 108 on the aluminum layer 110 may be at least one discrete point that may be a contact point where there is an electrical contact with a photovoltaic cell (not shown). In an embodiment, the pattern of the conductive layer is provided during the deposition of the copper layer 108 on the aluminum layer 110.

In a particular embodiment and as seen in FIG. 1A, the pattern is provided by removing at least a portion of the conductive layer. For instance, at least a portion of the conductive layer 106 may be removed from any layer to which is it disposed upon, such as the polymeric support layer 104. Any reasonable method of removing at least a portion of the conductive layer is envisioned. For instance, removal of the conductive layer 106 includes scoring or shaping a surface area 118 in any reasonable configuration. The scoring or shaping provides enhanced removal of the surface area 118 of the conductive layer 106. Any reasonable method of scoring or cutting the conductive layer 106 is envisioned. In a particular embodiment, the scoring or shaping includes scoring using at least one knife in a die cutting apparatus, such as two parallel knives spaced at any reasonable distance. In an exemplary embodiment, two parallel knives are spaces apart at about 0.5 millimeters (mm) to about 2.0 millimeters, such as about 1.0 millimeter apart. In an exemplary embodiment, at least a portion of the conductive layer 106 is scored or cut to a depth to remove at least a portion of the conductive layer. Although not illustrated, the polymeric support layer 104 may also be at least partially cut while still maintaining its structural integrity as a support for the conductive layer 106.

As seen in FIG. 1A, the conductive layer 106 is disposed on the polymeric support layer 104 with an adhesive layer 120 disposed there between. As illustrated, the adhesive layer 120 is disposed between the conductive layer 106 and the polymeric support layer 104. In an embodiment, the adhesive layer 120 is disposed in a layer having a uniform thickness. In another embodiment, at least a portion of the polymeric support layer 104 is substantially free of the adhesive layer 120 so as to allow easy removal of at least a portion of the patterned or scored conductive layer. “Substantially free” as used herein refers to a minimal quantity of adhesive in an adhesive-free portion 122, wherein the adhesive-free portion 122 contains adhesive having an average thickness that is less than about 20%, less than about 15%, less than about 10%, less than about 5%, or even less than about 1%, than the total thickness of the adhesive layer 120. In a particular embodiment, the adhesive layer 120 includes the adhesive-free portion 122 configured in a pattern. For instance, at least the portion of the surface of the polymeric support layer 104 that is substantially free of the adhesive layer 120 provides ease of removal of the conductive layer 106 after the surface area 118 of the conductive layer 106 is scored or shaped. In an embodiment, the pattern of the adhesive-free portion 122 on the polymeric support layer 104 is substantially the same as the pattern of the scored surface area 118 of the conductive layer 106. “Substantially the same” as used herein refers to the pattern of the adhesive-free portion 122 that is not greater than 5%, such as not greater than 2%, or even not greater than 1% in width, length, and shape than the pattern of the scored surface area 118 of the conductive layer 106. In a particular embodiment, the adhesive layer 120 pattern creating the adhesive-free portion 122 is configured on the polymeric support layer 104 such that even if there is a misalignment of the scored surface area 118 of the conductive layer 106, the scored surface area 118 of the conductive layer 106 to be removed is substantially free of the adhesive. In a further embodiment, the conductive layer 106 is patterned and cut having a tab area (not illustrated). The tab area can have a surface area configured and sized to initiate removal of the scored surface area 118 of the conductive layer 106. In a particular embodiment, the tab area may be substantially free of the adhesive. Removal of the scored or shaped surface area 118 of the conductive layer 106 includes any reasonable method such as by vacuum, a tack film (not illustrated) disposed over the scored or shaped surface area 118, the like, or a combination thereof.

In an embodiment, the conductive layer 106 is patterned with the use of a three dimensional surface. As seen in FIG. 1B, the conductive layer 106 is patterned with at least one three dimensional surface having an increased vertical height “Y”. For instance, the aluminum layer 110 is dimensioned such that it has an increased vertical height having any reasonable shape envisioned such as a rectangular shape, a trapezoidal shape, a pyramidal shape, or a rounded shape. In an embodiment, the aluminum layer 110 is increased with a vertical height prior to coating with the copper layer 108. In another embodiment, the aluminum layer 110 is increased with a vertical height after coating with the copper layer 108. Although the copper layer 108 is illustrated as being disposed on individual, discrete points on the aluminum layer 110, the copper layer may be disposed as a continuous layer (not illustrated). Further, the three dimensional surface may be provided with or without the polymeric support layer 104.

In a particular embodiment, the conductive surface 106 is raised in at least one region. In particular, the increased height of the conductive surface 106 may be used to reduce the distance between the conductive layer and a photovoltaic cell (not shown). The increased height may be achieved by any reasonable method. For instance, the increased height may be achieved by mechanically pushing the conductive layer 106. In an embodiment, the increased height may be provided either before placing the conductive layer 106 on the polymeric support layer 104 or after placing the conductive layer 106 on the polymeric support layer 104. Further, the conductive layer 106 may or may not have any further anti-oxidant layer on the conductive layer 106 prior to providing the three dimensional surface on the conductive layer 106. In an embodiment, the three dimensional surface may be achieved by sending the conductive layer 106 through a nip where at least one roller has a mesh pattern for the conductive layer 106 to be pushed therethrough, creating a three dimensional surface. In an embodiment, the three dimensional surface may be formed via pressure, a vacuum, or any combination thereof. In a particular embodiment, the three dimensional surface may be disposed in a pattern across the backsheet. For instance, the raised areas may have a predetermined pattern. Furthermore, the three dimensional surface may be supported with any reasonable material such that the raised surface does not flatten, i.e. decrease in height. For instance, once the conductive layer 106 has raised surfaces, any depressions on the bottom side of conductive layer 106 may be filled, for example, with an adhesive that may also be used to adhere the conductive layer 106 to an adjacent layer, such as the polymeric support layer 104.

In a particular embodiment, any number of anti-oxidation layers may be deposited on the conductive layer 106. For instance, the copper layer 108 may be deposited on the aluminum layer 110 followed by any number of inorganic layers, organic layers, or combination thereof. Further, the anti-oxidation layer may be deposited by any method envisioned. Further, the anti-oxidation layer may be patterned by any mention envisioned.

In an embodiment, the thickness of the polymeric support layer 104 provides a desirable substrate for the disposing the conductive layer 106 thereon. For instance, the thickness of the polymeric support layer 104 provides a desirable substrate for when the vapor deposition process is used. In an example, the polymeric support layer 104 having a thickness of about 10 microns to about 75 microns increases the throughput per batch during the vapor deposition process, providing an increased efficiency and lower cost of processing compared to a polymeric support layer 104 that has a thickness greater than the range described. In a particular embodiment, the sputtering process is accomplished in a closed vacuum chamber in a batch process, with a limited volume. The thickness of the substrate determines the linear length of the roll that can be processed per batch. Lowering the thickness of the laminate to be sputtered from a thickness of 300 micron to 100 micron can increase the thru put by more than 50% per batch. In an embodiment, the efficiency of the vapor deposition process is increased by at least about 20%, such at least about 30%, such as at least about 40%, or even greater than about 50% per batch with the polymeric support layer 104 having a thickness of about 10 microns to about 75 microns compared to a polymeric support layer 104 having a thickness greater than described.

In an embodiment, the polymeric support layer 104 and the barrier polymer layer 102 are disposed and adhered together to form the multilayer laminate 100. In an embodiment, the polymeric support layer 104 and the bather polymer layer 102 may be disposed and adhered together by any method. For instance, the polymeric support layer 104 may be disposed on the polyester layer 112 of the barrier polymer layer 102 by any means such as an adhesive bond, coextrusion, thermal bonding, ultrasonic bonding, or combination thereof. In a particular embodiment, the adhesive bond may be with the use of any adhesive layer (not shown) as described above. In a more particular embodiment, an adhesive layer may be applied by any method depending upon the adhesive material chosen. For instance, the adhesive may be coated or laminated. Any thickness of the adhesive layer may be envisioned with the adhesive layer being continuous, discontinuous, patterned, or combination thereof.

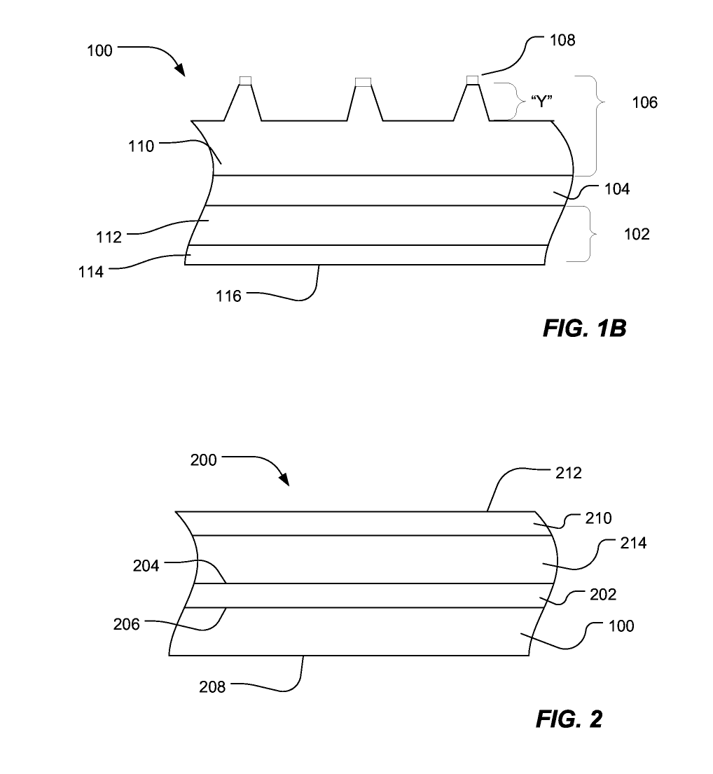

As seen in FIG. 2, the multilayer laminate 100 may be used with a photovoltaic device 200. Photovoltaic device 200 includes a photovoltaic component 202. The component 202 includes a front surface 204 and a back surface 206. The front surface 204 includes elements to receive sunlight and convert the sunlight into electrical current. In a particular example, the back surface 206 can be defined by a support for the elements of the front surface 204. The multilayer laminate backsheet 100 can be disposed over the back surface 206. The multilayer laminate backsheet 100 can form a back side outer surface 208 of the photovoltaic device 200 that is exposed to an external environment. In particular, the conductive layer of the multilayer laminate backsheet 100 is disposed next to the back surface 206 and the fluoropolymer layer of the multilayer laminate backsheet 100 is in contact with the external environment. The multilayer laminate backsheet 100 provides both a sealing surface to protect the photovoltaic component 202 as well as a material source to conduct current away from the photovoltaic component 202.

A protective layer 210 can be disposed over the front surface 204. The protective layer 210 can form an outer surface 212 configured to receive light, such as sunlight, to be converted to energy by the photovoltaic component 202. In a particular example, the protective layer 210 can be glass, a polymeric material, or combination thereof. In an embodiment, the protective layer 210 is a glass. In an embodiment, the protective layer 210 may include multilayer films including a fluoropolymer layer forming the outer surface, an adhesive layer underlying the fluoropolymer layer, a functional portion underlying the adhesive layer, or combination thereof. For example, the functional portion can function as a barrier to hinder water vapor transmission, corrosive gas diffusion, or a combination thereof.

The fluoropolymer layer that may form the outer surface of the protective layer 210 includes any fluoropolymer described for the multilayer laminate 100. In addition, the protective layer 210 may include an adhesive layer to adhere any adjacent layers. The adhesive layer can include any adhesive as described above. The protective layer 210 may further include a functional layer or layers. In an example, the functional layer or layers form a functional portion that includes at least one barrier layer to inhibit water vapor transfer, corrosive gas transfer, such as oxygen transfer, or a combination thereof. In a particular example, the protective layer 210 may include a functional layer or layers that can include a barrier polymer as described above such as a polyester, polycarbonate, or any combination thereof. When multiple layers are used for the protective layer 210, any thickness of each of the layers of the protective layer 210 is envisioned depending upon the final properties desired.

One or more intermediate layers 214 can be disposed between the protective layer 210 and the front surface 204 of the photovoltaic component 202. In an example, the one or more intermediate layers 214 can include an encapsulant as described above for the multilayer laminate. Such materials include, for example, natural or synthetic polymers including polyethylene (including linear low density polyethylene, low density polyethylene, high density polyethylene, etc.), polypropylene, nylon (polyamide), EPDM, polyester, polycarbonate, ethylene-propylene elastomer copolymer, copolymer of ethylene or propylene with acrylic or methacrylic acid, acrylate, methacrylate, ethylene-propylene copolymer, poly alpha olefin melt adhesive including, for example, ethylene vinyl acetate (EVA), ethylene butyl acrylate (EBA), ethylene methyl acrylate (EMA); ionomer (acid functionalized polyolefin generally neutralized as a metal salt), acid functionalized polyolefin, polyurethane including, for example, thermoplastic polyurethane (TPU), olefin elastomer, olefinic block copolymer, thermoplastic silicone, polyvinyl butyral, a fluoropolymer, such as a terpolymer of tetrafluoroethylene, hexafluoropropylene, and vinylidene fluoride; or any combination thereof. In an embodiment, the encapsulant is ethylene vinyl acetate (EVA). As illustrated, an intermediate layer 214 of an encapsulant can be disposed between the protective layer 210 and the photovoltaic component 202. Optionally, the intermediate layer 214 of the encapsulant can form part of the protective layer 210.

Any reasonable layer may further be envisioned within the photovoltaic device 200. Exemplary layers include an adhesive layer, a reinforcing layer, or any combination thereof. Further layers may include a layer that confers opacity against UV and visible light, color, improved dielectric resistance, or combination thereof. A reinforcing layer can include a reinforcement, such as a fibrous reinforcement. Any reinforcement material may be envisioned such as a polymer, a glass, a metal, or combination thereof. The fibrous reinforcement can be a woven fibrous reinforcement or a non-woven fibrous reinforcement. In an example, the reinforcement is a woven fibrous reinforcement, such as a glass fabric or scrim. The reinforcing layer may be a separate layer or contained within a layer to provide reinforcing properties to the final photovoltaic device 200. Further, any of the layers contained within the photovoltaic device 200 can include any additive envisioned, such as a flame retardant, an antioxidant, a scavenger, such as a desiccant or a getter, or other additive.

For maximum transmission of sunlight to the front surface 204 of the photovoltaic component 202, the protective layer 210 and the intermediate layer 214 can have a visible light transmission of at least 85% through the protective layer 210 and the intermediate layer 214. For example, the visible light transmission can be at least 90%, such as at least 92%. Visible light transmission is defined as light transmission for wavelengths between 400 nm and 750 nm. Visible light transmission includes electromagnetic radiation having a wavelength in a range of 400 nm to 750 nm. In another example, the protective layer 210 and the intermediate layer 214 have a desirable durability. For example, the protective layer 210 and the intermediate layer 214 have a desirable Delta-b Index, defined as the change in b* of the L*a*b* scale (CIE 1976) after a specified period of exposure to UVA radiation or UVB radiation using the method of the examples below.

The protective layer 210 and the intermediate layer 214 can be disposed on the photovoltaic component 202 to form the photovoltaic device 200 by any method envisioned. Further the photovoltaic component 202 may be disposed on the multilayer laminate 100 by any method envisioned. The photovoltaic device 200 further can include conductive interconnects, such as metallic interconnects and/or semiconductor interconnects (not illustrated). The device is typically held together in a framed structure. The resulting framed structure can be used to apply the photovoltaic device 200 on an exterior of a building as a part of an exterior wall, roof, siding, and the like.

Advantageously, the multilayer laminate provides an improved structure over conventional backsheets. Further, the process of making the multilayer laminate is improved. For instance, the heat stabilization provides a one-step process for both the cure of the fluoropolymer layer and the heating of the barrier polymer layer to increase the efficiency of the process as well as reduce the net shrinkage. For comparison, a barrier polymer layer that has not been heat stabilized typically has a net shrinkage of greater than 1.0%. With the heat stabilized barrier polymer layer, the net shrinkage is desirable improved. Accordingly, the dimensional stability of the final multilayer laminate having a heat stabilized barrier polymer layer is improved.

Additionally, a conventional backsheet typically has a single layer of aluminum or copper. Neither component separately is both cost efficient and conductively efficient. However, the combination of a copper layer and an aluminum layer has been found to be both cost efficient and conductively efficient. Aluminum has 66% of the conductivity of copper, but costs less than 33% of the cost of copper. The patterning of the conductive layer also can decrease the amount of aluminum, copper, or combination thereof used for the backsheet, thus further providing cost efficiency and conductive efficiency. Further, the use of the polymeric support layer when processing the copper layer of the conductive layer increases the efficiency of the deposition process of the copper layer on the aluminum layer, thus decreasing material cost, reducing deposition cost, and reducing production time.

The patterned conductive layer, such as including the inorganic layer, such as aluminum and copper, and the polymeric support layer, may be used in any application envisioned. Although primarily described as being disposed on a barrier polymer layer, the patterned conductive layer disposed on the polymeric support layer can be used with any substrate envisioned, such as any flexible or rigid substrate. Substrates include, for example, a polymer, a glass, a ceramic, a paper, a composite, a laminate, or any combination thereof. In an embodiment, the patterned conductive layer disposed on the polymeric support layer may be used with any rigid substrate, such as a glass substrate with or without the need for any barrier polymer layer.

Although illustrated and described as being used with a photovoltaic device, the multilayer laminate may be used with any other material, device, framed device, or the like, that may be envisioned. For instance, the multilayer laminate may be used for applications for buildings or structures. In an embodiment, the multilayer laminate may also be used with electronic devices, insulating glass assemblies, and the like that would be potentially exposed to environmental conditions. In an embodiment, further applications include antennas, electrical circuits, EMF shields, and the like.

Embodiments may be in accordance with any one or more of the items as listed below. A set of items are as follows:

Item 1. A multilayer laminate for a photovoltaic device comprising a barrier polymer layer comprising a fluoropolymer layer disposed on a polyester layer; a polymeric support layer disposed on the polyester layer of the barrier polymer layer; and a patterned conductive layer comprising a copper layer disposed on an aluminum layer, the aluminum layer disposed on the polymeric support layer.

Item 2. A method of making a multilayer laminate for a photovoltaic device comprising providing a barrier polymer layer comprising a fluoropolymer layer disposed on a polyester layer; disposing a conductive layer on a polymeric support layer, the conductive layer comprising a copper layer disposed on an aluminum layer, wherein the conductive layer is patterned; and disposing the polymeric support layer on the polyester layer of the barrier polymer layer.

Item 3. A photovoltaic device comprising a multilayer laminate backsheet comprising a barrier polymer layer comprising a fluoropolymer layer disposed on a polyester layer; a polymeric support layer disposed on the polyester layer of the barrier polymer layer; and a patterned conductive layer comprising a copper layer disposed on an aluminum layer, the aluminum layer disposed on the polymeric support layer.

Item 4. The multilayer laminate film, the method of making the multilayer laminate, or the photovoltaic device of any of the preceding items, wherein the patterned conductive layer includes at least one three dimensional surface having an increased vertical height.

Item 5. The multilayer laminate film, the method of making the multilayer laminate, or the photovoltaic device of item 4, wherein the increased vertical height has a rectangular shape, a trapezoidal shape, a pyramidal shape, or a rounded shape.

Item 6. The multilayer laminate film, the method of making the multilayer laminate, or the photovoltaic device of any of the preceding items, wherein the copper layer is disposed in a pattern on the aluminum layer to provide the patterned conductive layer.

Item 7. The multilayer laminate, the method of making the multilayer laminate, or the photovoltaic device of any one of the preceding items, wherein the copper layer is disposed on the aluminum layer by a sputtering process, an evaporation process, an ultrasonic bonding process, or combination thereof.

Item 8. The multilayer laminate film, the method of making a multilayer laminate film, or the photovoltaic device of any of the preceding items, wherein at least a portion of the conductive layer is removed from the polymeric layer.

Item 9. The multilayer laminate film, the method of making the multilayer laminate, or the photovoltaic device of item 8, wherein removal of the conductive layer includes scoring a surface area of the conductive layer.

Item 10. The multilayer laminate film, the method of making the multilayer laminate, or the photovoltaic device of item 9, wherein at least a portion of the polymeric layer that is directly adjacent to the surface area of the conductive layer for removal is substantially free of an adhesive.

Item 11. The multilayer laminate, the method of making the multilayer laminate, or the photovoltaic device of any of the preceding items, further comprising an adhesive disposed between the aluminum layer and the polymeric support layer.

Item 12. The multilayer laminate, the method of making the multilayer laminate, or the photovoltaic device of item 11, wherein the adhesive is provided on the polymeric support layer in a pattern.

Item 13. The multilayer laminate, the method of making the multilayer laminate, or the photovoltaic device of item 11, wherein the adhesive is a polyolefin, a copolymer of ethylene and vinyl acetate, a vinyl acetate copolymer, an acrylate copolymer such as poly(octadecyl acrylate), a functionalized polyolefin, a polyurethane, a polyvinyl butyral, a silicone, a fluoropolymer, an epoxy, or any combination thereof.

Item 14. The multilayer laminate, the method of making the multilayer laminate, or the photovoltaic device of any of the preceding items, wherein the aluminum layer has a thickness of about 4 micrometers to about 100 micrometers, such as about 25 micrometers to about 100 micrometers.

Item 15. The multilayer laminate, the method of making the multilayer laminate, or the photovoltaic device of any of the preceding items, wherein the copper layer has a thickness of about 10 nanometers to about 300 nanometers.

Item 16. The multilayer laminate, the method of making the multilayer laminate, or the photovoltaic device of any of the preceding items, wherein the polymeric support layer comprises a polyester layer.

Item 17. The multilayer laminate, the method of making the multilayer laminate, or the photovoltaic device of item 16, wherein the polyester layer of the polymeric support layer is a polyethylene terephthalate.

Item 18. The multilayer laminate, the method of making the multilayer laminate, or the photovoltaic device of any of the preceding items, wherein the polymeric support layer has a thickness of about 10 microns to about 325 microns, such as about 10 microns to about 75 microns.

Item 19. The multilayer laminate, the method of making the multilayer laminate, or the photovoltaic device of any of the preceding items, wherein the barrier polymer layer is heat stabilized.

Item 20. The multilayer laminate, the method of making the multilayer laminate, or the photovoltaic device of item 19, wherein the heat stabilized barrier polymer layer has a net shrinkage of less than about 1.0%.

Item 21. The multilayer laminate, the method of making the multilayer laminate, or the photovoltaic device of item 19, wherein the heat stabilization includes heating the barrier polymer layer at a temperature to not less than about 40° C. below a glass transition temperature of the polymeric layer within the barrier layer.

Item 22. The multilayer laminate, the method of making the multilayer laminate, or the photovoltaic device of item 21, wherein the heat stabilization includes maintaining a tension of less than about 10 pounds per lineal foot on the barrier polymer layer during heating.

Item 23. The multilayer laminate, the method of making the multilayer laminate, or the photovoltaic device of any of the preceding items, wherein the fluoropolymer is selected from the group consisting of polyvinyl fluoride (PVF), polytetrafluoroethylene (PTFE), perfluoroalkylvinyl ether (PFA or MFA), fluorinated ethylene-propylene copolymer (FEP), ethylene tetrafluoroethylenecopolymer (ETFE), polyvinylidene fluoride (PVDF), polychlorotrifluoroethylene (PCTFE), TFE copolymers with VF2 or HFP, ethylene chlorotrifluoroethylene copolymer (ECTFE), a copolymer of ethylene and fluorinated ethylene propylene (EFEP), a terpolymer of tetrafluoroethylene, hexafluoropropylene, and vinylidene fluoride (THV), a terpolymer of tetrafluoroethylene, hexafluoropropylene, and ethylene (HTE), and a combination thereof.

Item 24. The multilayer laminate, the method of making the multilayer laminate, or the photovoltaic device of any of the preceding items, wherein the fluoropolymer layer has a thickness of about 1 micrometers to about 50 micrometers, such as about 1 micrometer to about 30 micrometers.

Item 25. The multilayer laminate, the method of making the multilayer laminate, or the photovoltaic device of any one of the preceding items, wherein the polyester layer of the barrier polymer layer is a polyethylene terephthalate.

Item 26. The multilayer laminate, the method of making the multilayer laminate, or the photovoltaic device of any of the preceding items, wherein the polyester layer of the barrier polymer layer has a thickness of about 12 micrometers to about 325 micrometers, such as about 12 micrometers to about 275 micrometers.

Item 27. The multilayer laminate, the method of making the multilayer laminate, or the photovoltaic device of any of the preceding items, further comprising an adhesive disposed between the polymeric support layer and the barrier layer.

Item 28. The multilayer laminate, the method of making the multilayer laminate, or the photovoltaic device of item 27, wherein the adhesive is a polyolefin, a copolymer of ethylene and vinyl acetate, vinyl acetate copolymer, acrylate copolymer such as poly(octadecyl acrylate), functionalized polyolefin, a polyurethane, a polyvinyl butyral, a silicone, a fluoropolymer, a epoxy, or any combination thereof.

Item 29. The multilayer laminate, the method of making the multilayer laminate, or the photovoltaic device of any of the preceding items, further comprising an oxidation resistant material disposed on the copper layer.

Item 30. The multilayer laminate, the method of making the multilayer laminate, or the photovoltaic device of item 29, wherein the oxidation resistant material comprises an inorganic material, an organic material such as a triazole, or combination thereof.

Item 31. The multilayer laminate, the method of making the multilayer laminate, or the photovoltaic device of item 29, wherein the oxidation resistant material is an inorganic material disposed on the copper layer by a sputtering process or an evaporation process.

Item 32. The multilayer laminate, the method of making the multilayer laminate, or the photovoltaic device of item 29, wherein the oxidation resistant material has a thickness of about 1 nanometer to about 25 nanometer.

Note that not all of the activities described above in the general description or the examples are required, that a portion of a specific activity may not be required, and that one or more further activities may be performed in addition to those described. Still further, the order in which activities are listed are not necessarily the order in which they are performed.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

As used herein, the terms “comprises,” “comprising,” “includes,” “including,” “has,” “having” or any other variation thereof, are intended to cover a non-exclusive inclusion. For example, a process, method, article, or apparatus that comprises a list of features is not necessarily limited only to those features but may include other features not expressly listed or inherent to such process, method, article, or apparatus. Further, unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” are employed to describe elements and components described herein. This is done merely for convenience and to give a general sense of the scope of the invention. This description should be read to include one or at least one and the singular also includes the plural unless it is obvious that it is meant otherwise.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

After reading the specification, skilled artisans will appreciate that certain features are, for clarity, described herein in the context of separate embodiments, may also be provided in combination in a single embodiment. Conversely, various features that are, for brevity, described in the context of a single embodiment, may also be provided separately or in any subcombination. Further, references to values stated in ranges include each and every value within that range.

What is claimed is:

1. A multilayer laminate for a photovoltaic device comprising:
a barrier polymer layer comprising a fluoropolymer layer disposed on a polyester layer;
a polymeric support layer disposed on the polyester layer of the barrier polymer layer; and
a patterned conductive layer comprising a copper layer disposed on an aluminum layer, the aluminum layer disposed on the polymeric support layer.

2. A method of making a multilayer laminate for a photovoltaic device comprising:
providing a barrier polymer layer comprising a fluoropolymer layer disposed on a polyester layer;
disposing a conductive layer on a polymeric support layer, the conductive layer comprising a copper layer disposed on an aluminum layer, wherein the conductive layer is patterned; and
disposing the polymeric support layer on the polyester layer of the barrier polymer layer.

3. A photovoltaic device comprising:
a multilayer laminate backsheet comprising:
a barrier polymer layer comprising a fluoropolymer layer disposed on a polyester layer;
a polymeric support layer disposed on the polyester layer of the barrier polymer layer; and
a patterned conductive layer comprising a copper layer disposed on an aluminum layer, the aluminum layer disposed on the polymeric support layer.

4. The multilayer laminate film in accordance with claim 1, wherein the patterned conductive layer includes at least one three dimensional surface having an increased vertical height.

5. The multilayer laminate film in accordance with claim 1, wherein the copper layer is disposed in a pattern on the aluminum layer to provide the patterned conductive layer.

6. The multilayer laminate in accordance with claim 1, wherein the copper layer is disposed on the aluminum layer by a sputtering process, an evaporation process, an ultrasonic bonding process, or combination thereof.

7. The multilayer laminate film in accordance with claim 1, wherein at least a portion of the conductive layer is removed from the polymeric layer.

8. The multilayer laminate film in accordance with claim 7, wherein removal of the conductive layer includes scoring a surface area of the conductive layer.

9. The multilayer laminate film in accordance with claim 8, wherein at least a portion of the polymeric layer that is directly adjacent to the surface area of the conductive layer for removal is substantially free of an adhesive.

10. The multilayer laminate in accordance with claim 1, further comprising an adhesive disposed between the aluminum layer and the polymeric support layer.

11. The multilayer laminate in accordance with claim 10, wherein the adhesive is provided on the polymeric support layer in a pattern.

12. The multilayer laminate in accordance with claim 1, wherein the polymeric support layer comprises a polyester layer.

13. The multilayer laminate, the method of making the multilayer laminate, or the photovoltaic device of claim 12, wherein the polyester layer of the polymeric support layer is a polyethylene terephthalate.

14. The multilayer laminate in accordance with claim 1, wherein the polymeric support layer has a thickness of about 10 microns to about 325 microns, such as about 10 microns to about 75 microns.

15. The multilayer laminate in accordance with claim 1, wherein the barrier polymer layer is heat stabilized.

16. The multilayer laminate in accordance with claim 15, wherein the heat stabilized barrier polymer layer has a net shrinkage of less than about 1.0%.

17. The multilayer laminate in accordance with claim 15, wherein the heat stabilization includes heating the barrier polymer layer at a temperature to not less than about 40° C. below a glass transition temperature of the polymeric layer within the barrier layer.

18. The multilayer laminate in accordance with claim 17, wherein the heat stabilization includes maintaining a tension of less than about 10 pounds per lineal foot on the barrier polymer layer during heating.

19. The multilayer laminate in accordance with claim 1, wherein the polyester layer of the barrier polymer layer is a polyethylene terephthalate.

20. The multilayer laminate in accordance with claim 1, further comprising an oxidation resistant material disposed on the copper layer.
